(19) United States
(12) Patent Application Publication
(10) Pub. No.: US 2003/0159652 A1
(43) Pub. Date: Aug. 28, 2003

(54) Heating injection apparatus for vapor liquid delivery system

(75) Inventors: Neng-Hui Yang, Hsin-Chu City (TW); Yi-Fang Chiang, Taipei Hsien (TW); Cheng-Yuan Tsai, Yun-Lin (TW); Wen-Yi Hsieh, Hsin-Chu City (TW)

Correspondence Address: MERCHANT & GOULD PC, P.O. BOX 2903, MINNEAPOLIS, MN, 55402-0903, US

(73) Assignee: United Microelectronics Corp., Hsin-Chu City (TW)

(21) Appl. No.: 10/084,398

(22) Filed: Feb. 25, 2002

(51) Int. Cl. C23C 16/00

(52) U.S. Cl. 118/715; 118/726

(57) ABSTRACT

A heating injection apparatus for vapor liquid delivery system includes inert gas purging part and thermostat device. Inert gas purging parts includes a liquid injector, a three-way valve, an exhausting branch and a purging gas. The three-way valve is used to connect purging gas, injector and exhausting branch. Liquid source resides in front of the liquid injector, and be injected into a gas line by liquid injector, besides the purging gas is used to purging out the liquid source remains on liquid injector to prevent polymerization. The temperature setting of thermostat device can be adjusted to meet liquid source requirement, and used to heating gas to demand production temperature before the gas enters the CVD system, and the thermostat device heats gas more efficiently, quickly and keep the gas temperature constant.

### BACKGROUND OF THE INVENTION

1. Field of the Invention

This invention relates in general to the fields of vapor liquid delivery system. More particularly, the present invention relates to a vapor liquid delivery system for chemical vapor deposition (CVD) process.

2. Description of the Prior Art

The controlled deposition of thin organic and inorganic films is an important step in the manufacture of integrated circuits. These films are deposited to remain as an inherent part of the device structure, or to constitute intermediate layers that are used for particular processing steps and then removed. One of the methods for the deposition of thin films is chemical vapor deposition (CVD).

The FIG. 1 illustrates a prior vapor liquid delivery system used to CVD process. A three-way valve 105 is used to connect a liquid source 100, a purging gas 130 and a liquid injector 115. The liquid source 100 is atomized and injected into this prior vapor liquid delivery system by liquid injector 115. The atomized liquid source 100 will enter gas-mixing device 120 with other process gases 125. However the liquid source 100 that resides in the front liquid injector 115 has a high risk of contacting with other reactive process gases to induce polymerization, especially soaking in high temperature. And a continuous purging out procedure of the prior vapor liquid delivery system need to be executed by He to purge out the liquid between valve 105 and injector 115 to prevent polymerization. That would impact machine uptime.

Furthermore, the heating passage of the prior vapor liquid delivery system is also too short to provide enough time to heat process gases, which has a high potential to reduce the temperature of vapor and cause condensation.

### SUMMARY OF THE INVENTION

In accordance with the present invention, a heating injection apparatus for vapor liquid delivery system, one object of the present invention is isolated liquid source from reaction chamber efficiently and prevents to induce polymerization.

Another object of the present invention is providing a heating means can heat process gases more efficiently and keep their temperature constant, and it can also maintain the temperature of vapor and prevent further condensation.

Another object of the present invention is stabilizing the flow of liquid prior to introduction to the reaction chamber. This would improve the repeatability of film deposition.

Another object of the present invention is to provide a purging procedure to purge the liquid between the valve and injector to prevent polymerization and other processing to be executed simultaneously. This in turn would improve machine uptime.

The present invention is a heating injection apparatus for vapor liquid delivery system. This apparatus implements a thermostat device to heat process gases and an inert gas purging module to isolate liquid source from other process gases, the heating injection apparatus includes a inert gas purging parts and a thermostat device. The heating source of this thermostat device can be a heating coil or infrared ray, and the temperature setting of thermostat device can be adjusted to meet liquid source requirement.

In accordance with the present invention, an inert gas purging part includes a liquid injector, a three-way valve, an exhausting branch and a purging nozzle. Liquid source resides in the front of a liquid injector, and this liquid source will be injected into a gas line through a liquid injector. The three-way valve disposing between the liquid source and liquid injector, and the three-way valve is used to control access of three pathways here and to isolate from process gases. One passageway of the three-way valve is connected to a purging gas that is used to purge the liquid source remains in the liquid injector. The purging procedure is used to purge the liquid source between the three-way valve and the liquid injector to prevent polymerization, thus improving machine uptime.

The thermostat device of the present invention is used to heat gas to demanded production temperature before the gas enters reaction chamber. The thermostat device heats gas more efficiently, and quickly to keep the gas temperature constant. And the thermostat device can also maintain the temperature of vapor and prevent further condensation.

In accordance with the present invention, a liquid heating injection apparatus for vapor liquid delivery system improves the previous disadvantages of prior art. The liquid heating injection apparatus of present invention can continuously purging the liquid that remains inside the injector to prevent polymerization. And the liquid heating injection apparatus of the present invention solves a short heating problem relate to can not provide enough time to heat process gases, which has a high potential to reduce the temperature of vapor and cause further condensation.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 is a scheme of vapor liquid delivery system of prior art.

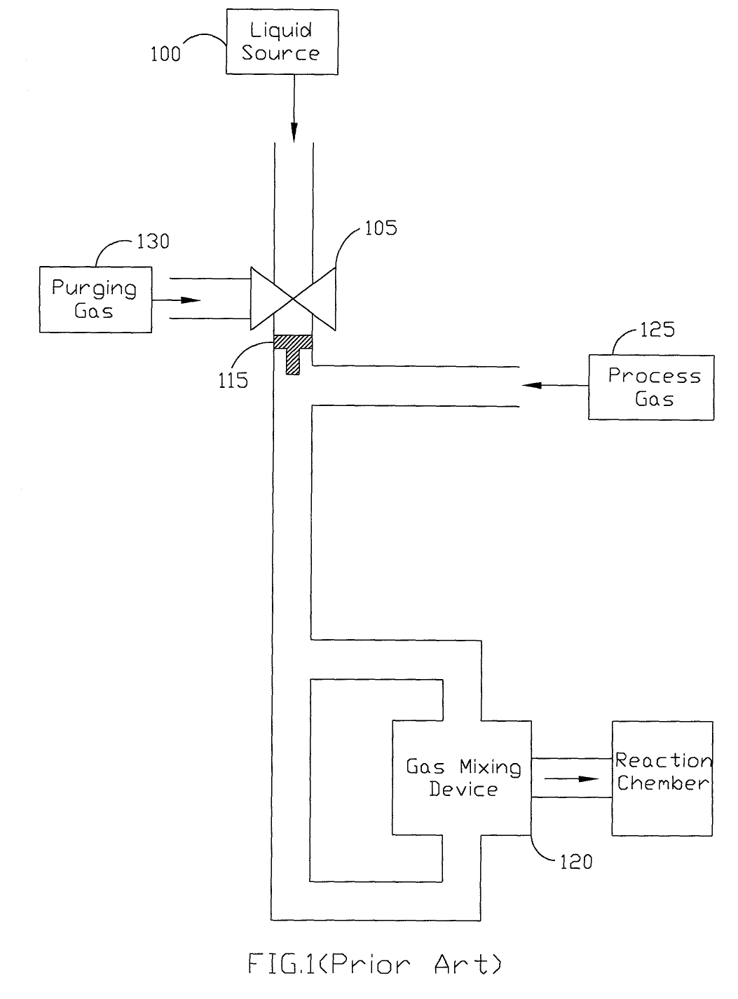

FIG. 2 is a preferred embodiment scheme of vapor liquid delivery system according to the present invention.

### DESCRIPTION OF THE PREFERRED EMBODIMENT

Some sample embodiments of the invention will now be described in greater detail. Nevertheless, it should be noted that the present invention can be practiced in a wide range of other embodiments besides those explicitly described, and the scope of the present invention is expressly not limited except as specified in the accompanying claims.

The present invention is a liquid heating injection apparatus for vapor liquid delivery system, and this apparatus implements a thermostat device to heat process gases and an inert gas purging module to isolate liquid source from other process gases.

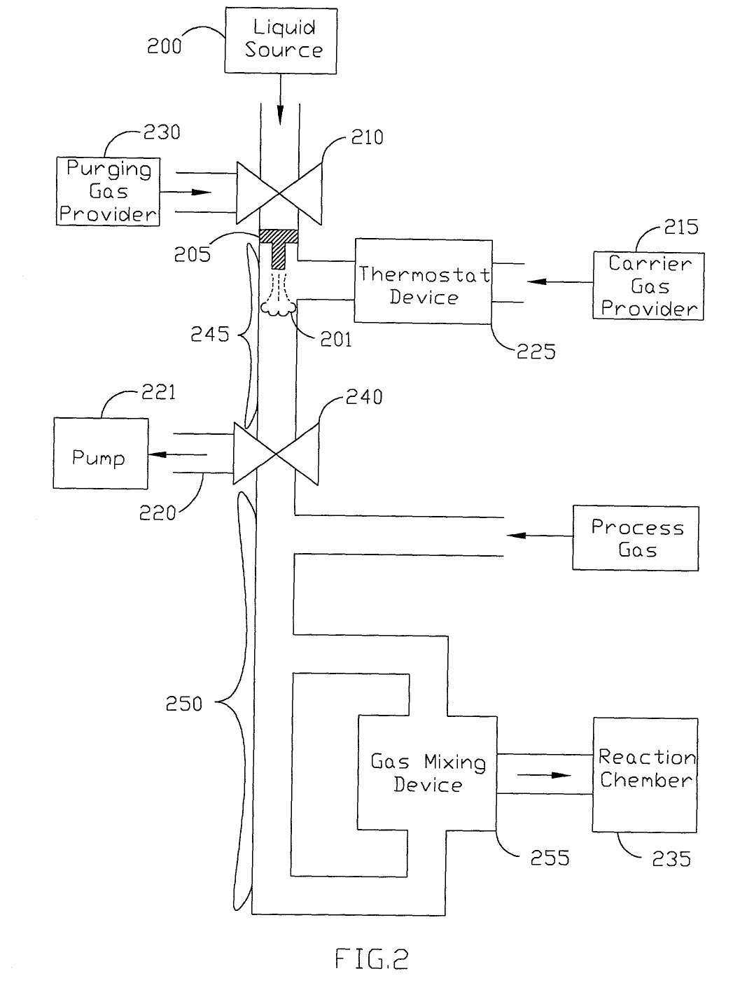

In FIG. 2, shown a preferred embodiment of liquid heating inject apparatus of the present invention for vapor liquid delivery system used. A liquid source 200, which resides in the front of liquid injector 205, the liquid source material in this preferred embodiment is TMCTS (1, 3, 5, 7, Tetramethylcyclotetrasiloxane) C₄H₁₆O₄Si₄, in another embodiment the liquid source can be another required materials. Liquid source 200 will be atomized and then injected into gas line 245 by liquid injector 205. There is a first three-way valve 210 disposing between liquid source 200 and liquid injector 205, and the first three-way valve 210 is used to control the access of the first three-way valve 210 and isolate from process gases.

The one passageway of the first three-way valve 210 is connected to a purging gas provider 230 that is used to purge the liquid source 200 that remains inside the liquid injector 205. The purging gas is He in this preferred embodiment of the prevent invention. In some embodiments the purging gases can be N₂, CO₂, Ar or other inert gases.

In FIG. 2, a branch 220 diverts to a pump 221. The branch 220 is used to stabilize pressure and speed of vapor flow of the vapor liquid delivery system. And the branch 220 can also be used as an exhausting branch. A second three-way valve 240 connected to the exhausting branch 220, gas line 245 and delivery line 250. And the purging gas 230 made the liquid source 200 has no chance to come in contact with other reactive process gases to induce polymerization, due to the purging gas always flushes the gas line 245 and is diverted to pump via exhausting branch 220. Purging procedures purge the liquid source remaining between the first three-way valve 210 and liquid injector 205, and then the exhausting branch 220 exhausts the purged gas. The purging procedure and other processes can be executed simultaneously and it would improve the machine uptime.

Continuously referring to FIG. 2, a carrier gas 215 before entering the gas line 245 has been heated by a thermostat device 225. The carrier gas 215 is used to carry atomized liquid source 201 that is injected by liquid injector 205, and then the carrier gas 215 delivers the atomized liquid source 201 through delivery line 250 into gas-mixing device 255. The thermostat device 225 is used to heat the carrier gas 215 to the demanded production temperature before the carrier gas 215 enters the vapor liquid delivery system. The thermostat device 225 heats the gas more efficiently, quickly and holds the gas temperature constant. And the thermostat device 225 can also maintains the temperature of vapor and prevent further condensation caused by a temperature decrease when carrier gas 215 is mixed with atomized liquid source 201.

In this preferred embodiment of the present invention, the temperature of the carrier gas to carry atomized liquid source TMCTS in the delivery line 250 at a temperature no less than 350° C., but not greater than 450° C., and the preferred temperature being 400° C. The heating source of thermostat device in this preferred embodiment of present invention can be heating coil or infrared ray, and the temperature setting of the thermostat device can be adjusted to meet the demand production requirement. In other embodiment the thermostat device can be other adjustable heating apparatus.

The atomized liquid source 201 had been carried by carrier gas 215 and other process gases will along the delivery line 250 enters a gas-mixing device 255, and the gas-mixing device 255 connect a reaction chamber 235 to performing chemical vapor deposition process.

Although specific embodiments have been illustrated and described, it will be obvious to those skilled in the art that various modifications may be made without departing from what is intended to be limited solely by the appended claims.

What is claimed is:

1. A liquid injection module for vapor liquid delivery system, said liquid injection module comprising:
a liquid injector, said liquid injector is used to inject a liquid source and make said liquid source atomized;
a purging gas provider, said purging gas provider is used to provide a purging gas to purge out said liquid source that remain inside said liquid injector;
a first three-way valve, said first three-way valve is used to connect said liquid source, said purging gas provider and said liquid injector; and
a exhausting branch, said exhausting branch disposes adjacent said liquid injector, and said exhausting branch is used to exhaust redundant said liquid source that purged by purging gas.

2. The liquid injection module according to claim 1, wherein said purging gas is selected from the group consisting of nitrogen, CO₂, Ar and He.

3. The liquid injection module according to claim 1, further comprising a carrier gas, said carrier gas is used to carry said atomized liquid source.

4. The liquid injection module according to claim 3, wherein said carrier gas is TMCTS (1,3,5,7, Tetramethylcyclotetrasiloxane) C₄H₁₆O₄Si₄.

5. The liquid injection module according to claim 1, further comprising a second three-way valve, wherein said second three-way valve connect said exhausting branch, a gas line and a delivery line, said gas line depositing between said liquid injector and said second three-way valve, and said second three-way valve is used to control flow between said exhausting branch and said liquid injector.

6. The liquid injection module according to claim 5, further comprising a carrier gas provider, said carrier gas provider is used to provide carrier gas to carry said atomized liquid source.

7. The liquid injection module according to claim 6, wherein said carrier gas is TMCTS (1,3,5,7, Tetramethylcyclotetrasiloxane) C₄H₁₆O₄Si₄.

8. A heating injection apparatus for vapor liquid delivery system use in chemical vapor deposition (CVD) process, said heating injection apparatus comprising:
a liquid injector, said liquid injector is used to inject a liquid source and make said liquid source atomized while said liquid source injecting;
a purging gas provider, said purging gas provider is used to provide purge gas to purge out said liquid source that remain inside said liquid injector;
a first three-way valve, said first three-way valve is used to connect said liquid source, said purging gas provider and said liquid injector;
a exhausting branch, said exhausting branch disposes adjacent said liquid injector, and said exhausting branch is used to exhaust redundant said liquid source that purged by purging gas; and
a heating means for heating gases, said heating mean depositing between said liquid injector and a carrier gas provider, said carrier gas provider is used to provide carrier gas to carry said atomized liquid source.

9. The heating liquid injection apparatus according to claim 8, wherein said purging gas is selected from the group consisting of nitrogen, CO₂, Ar and He.

10. The heating liquid injection apparatus according to claim 8, wherein said heating means for heating gases is a thermostat device, and the heating source of said thermostat device is selected from the device consisting of heating coil and infrared ray.

11. The heating liquid injection apparatus according to claim 10, wherein said thermostat device is used to heat said carrier gas.

12. The heating liquid injection apparatus according to claim 8, wherein said carrier gas is TMCTS (1,3,5,7, Tetramethylcyclotetrasiloxane) C₄H₁₆O₄Si₄.

13. The heating liquid injection apparatus according to claim 8, further comprising a second three-way valve, wherein said second three-way valve connect said exhausting branch, a gas line, a delivery line, and said gas line is a passage that deposited between said liquid injector and said second three-way valve.

14. A heating liquid injection apparatus for vapor liquid delivery system use in chemical vapor deposition (CVD) process, said heating injection apparatus comprising:
a liquid injector, said liquid injector is used to inject a liquid source and make said liquid source to become atomization while said liquid source injecting;
a purging gas provider, said purging gas provider is used to provide purging gas to purge out said liquid source that remain inside said liquid injector;
a carrier gas provider, said carrier gas provider is used to provide carrier gas to carry said atomized liquid source;
a first three-way valve, said first three-way valve is used to connect said liquid source, said purging gas provider and said liquid injector.
a exhausting branch, said exhausting branch disposes adjacent said liquid injector, and said exhausting branch is used to exhaust redundant said liquid source that been purged by purging gas to prevent polymerization around said liquid injector;
a second three-way valve, said second three-way valve connect said exhausting branch, a gas line and a delivery line, said gas line is the passage that deposited between said liquid injector and said second three-way valve, and said second three-way valve is used to control flow between said exhausting branch and said liquid injector; and
a thermostat device depositing between said liquid injector and said carrier gas provider, said thermostat device is used to heat carrier gas, and said thermostat device is selected from the device consisting of heating coil and infrared ray.

15. The heating liquid injection apparatus according to claim 14, wherein said purging gas is selected from the group consisting of nitrogen, CO₂, Ar and He.

16. The heating liquid injection apparatus according to claim 14, wherein said carrier gas is TMCTS (1,3,5,7, Tetramethylcyclotetrasiloxane) C₄H₁₆O₄Si₄.
